(19) United States
(12) Patent Application Publication
(10) Pub. No.: US 2025/0285918 A1
(43) Pub. Date: Sep. 11, 2025

(54) METHODS OF DEPOSITING IRIDIUM-CONTAINING FILMS FOR SEMICONDUCTOR DEVICES

(71) Applicant: Applied Materials, Inc., Santa Clara, CA (US)

(72) Inventors: Chandan Das, Singapore (SG); Chandan Kr Barik, Singapore (SG); Andrea Leoncini, Singapore (SG); Jiecong Tang, Singapore (SG)

(73) Assignee: Applied Materials, Inc., Santa Clara, CA (US)

(21) Appl. No.: 18/598,628

(22) Filed: Mar. 7, 2024

(51) Int. Cl. H01L 21/768; C23C 16/04; C23C 16/18

(52) U.S. Cl. CPC H01L 21/76846; C23C 16/045; C23C 16/18

(57) ABSTRACT

Methods of depositing iridium-containing films are described. Methods of manufacturing interconnect structures as part of a microelectronic device fabrication process are also described. The methods include forming a dielectric layer including at least one feature defining a gap having sidewalls and a bottom on a substrate. The methods further include forming a blocking layer on the bottom by exposing the substrate to a blocking compound; selectively depositing an iridium-containing film on the sidewalls; removing the blocking layer; and performing a gap fill process to fill the gap with a gapfill material.

### TECHNICAL FIELD

Embodiments of the disclosure generally relate to methods of depositing iridium-containing films. In particular, embodiments of the disclosure are directed to methods of depositing iridium-containing films for high aspect ratio structures and for barrier, liner, and channel material applications in back-end-of-line (BEOL) processes.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both metal lines and metal vias and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption.

A conventional interconnect structure, such as a copper interconnect structure, for example, includes a barrier layer and/or a metal liner deposited on the sidewalls of a gap that provide a via, the sidewalls made of a dielectric material, providing good adhesion and preventing conductive metal, such as copper, from diffusing into the dielectric layer. Barrier layers can typically be the largest contributor to via resistance due to high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

The advancing complexity of advanced microelectronic devices is placing stringent demands on currently used deposition techniques. Unfortunately, there are a limited number of viable precursors to provide films with suitable crystallinity, grain size, continuity and electrical conductivity for microelectronic device fabrication processes. In addition, precursors that often meet these properties still suffer from poor long-term stability and lead to thin films that contain elevated concentrations of contaminants such as oxygen, nitrogen, and/or halides that are often deleterious to the target film application.

Accordingly, there is a need for methods for depositing material layers that improve performance of interconnects, for example, reducing via resistance and improving deposition selectivity.

### SUMMARY

One or more embodiments of the disclosure are directed to a method of depositing an iridium-containing film. In some embodiments, the method comprises exposing a semiconductor substrate to an iridium-containing precursor and a reactant to form the iridium-containing film, the iridium-containing precursor comprising one or more of

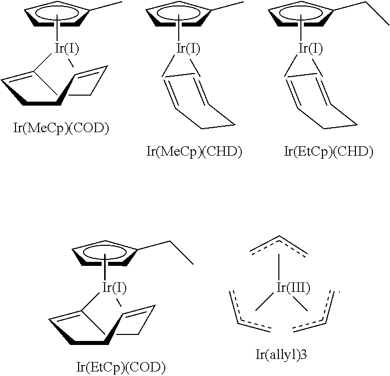

Additional embodiments of the disclosure are directed to a method of depositing an iridium-containing film. In some embodiments, the method comprises exposing a semiconductor substrate to an iridium-containing precursor and a reactant to form an iridium-containing film, the semiconductor substrate comprising at least one feature, the at least one feature defining a gap having sidewalls comprised of a dielectric material and a bottom comprised of a metallic material, the iridium-containing precursor comprising one or more of

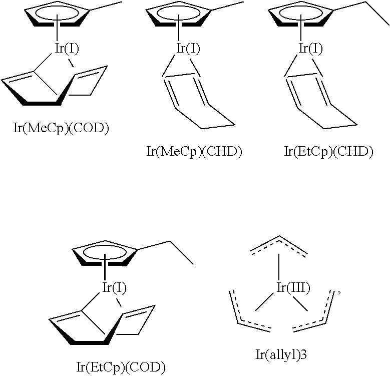

wherein the method is performed at a temperature in a range of from 100° C. to 500° C. and a pressure in a range of from 0.1 Torr to 760 Torr, the iridium-containing film comprises greater than or equal to about 99% iridium atoms, and the iridium-containing film contains essentially no halogen atoms.

Further embodiments of the disclosure are directed to a method of manufacturing a microelectronic device. In some embodiments, the method comprises forming a dielectric layer on a substrate, the dielectric layer including at least one feature defining a gap having sidewalls and a bottom; forming a blocking layer on the bottom; selectively depositing an iridium-containing film on the sidewalls; removing the blocking layer; and performing a gap fill process to fill the gap with a gapfill material comprising one or more of copper (Cu), cobalt (Co), ruthenium (Ru), tungsten (W), or molybdenum (Mo).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional schematic view of a substrate in accordance with one or more embodiments of the disclosure;

FIG. 1B illustrates a cross-sectional schematic view of a substrate in accordance with one or more embodiments of the disclosure;

FIG. 1C illustrates a cross-sectional schematic view of a substrate in accordance with one or more embodiments of the disclosure;

FIG. 2A illustrates a process flow diagram of a method of manufacturing a microelectronic device in accordance with one or more embodiments of the disclosure;

FIG. 2B illustrates a cross-sectional schematic view of a microelectronic device including a gap having sidewalls and a bottom with a blocking layer formed on the bottom of the gap in accordance with one or more embodiments of the disclosure;

FIG. 2C illustrates an iridium-containing film selectively deposited on the sidewalls of the gap of FIG. 2B in accordance with one or more embodiments of the disclosure;

FIG. 2D illustrates removal of the blocking layer formed in FIG. 2B in accordance with one or more embodiments of the disclosure; and

FIG. 2E illustrates a gap fill process filling the gap of FIG. 2B with a gapfill material in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the microelectronic device in use or operation in addition to the orientation depicted in the Figures. For example, if the microelectronic device in the Figures is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Iridium is a proposed material for integration owing to its high melting point (ability to withstand high current densities), exceptional density, and ability to conduct electrical current. Iridium and iridium-containing films have attractive material and conductive properties.

The iridium-containing films according to one or more embodiments can advantageously be used in memory and logic applications as, for example, a barrier layer, metal liner, and/or channel material. The iridium-containing film according to one or more embodiments can advantageously extend the metal fill and capping applications to advanced nodes, such as enabling conductive metal reflow, e.g., one or more of copper (Cu), cobalt (Co), tungsten (W), ruthenium (Ru), and/or molybdenum (Mo) reflow, in 3 nm node, 2 nm node, 1.4 nm node, and beyond, low resistivity in the middle-of-line (MOL) and back-end of line (BEOL), and memory applications. The iridium-containing films according to one or more embodiments can advantageously be used in high aspect ratio structures in BEOL processes.

Embodiments of the present disclosure also provide methods of manufacturing interconnect structures in a microelectronic device fabrication process. Some embodiments of the disclosure provide methods for improving performance of interconnects. Interconnects comprise metal lines that transfer current within the same device layer, and metal vias that transfer current between layers. These metal lines and metal vias are formed with conductive metal such as one or more of copper (Cu), cobalt (Co), ruthenium (Ru), tungsten (W), or molybdenum (Mo) in gaps formed within the device. In one or more embodiments, a dielectric layer comprises at least one feature defining a gap including sidewalls and a bottom. In one or more embodiments, the gap comprises the metal lines and the metal vias. In one or more embodiments, each of the metal lines have a sidewall and a bottom. In one or more embodiments, each of the metal vias have a sidewall and a bottom. As used herein, unless specified otherwise, reference to the “bottom of the gap” is intended to mean the bottom of the metal via, which is nearest the substrate.

In one or more embodiments, microelectronic devices described herein comprise at least one top interconnect structure that is interconnected to at least one bottom interconnect structure. Embodiments of the present disclosure provide microelectronic devices and methods of manufacturing microelectronic devices that improve performance of interconnects, for example, reducing via resistance.

One or more embodiments are directed to a method of manufacturing a microelectronic device. The method comprises: forming a dielectric layer on a substrate, the dielectric layer including at least one feature defining a gap having sidewalls and a bottom; forming a blocking layer on the bottom; selectively depositing an iridium-containing film on the sidewalls; removing the blocking layer; and performing a gap fill process to fill the gap with a gapfill material comprising one or more of copper (Cu), cobalt (Co), ruthenium (Ru), tungsten (W), or molybdenum (Mo).

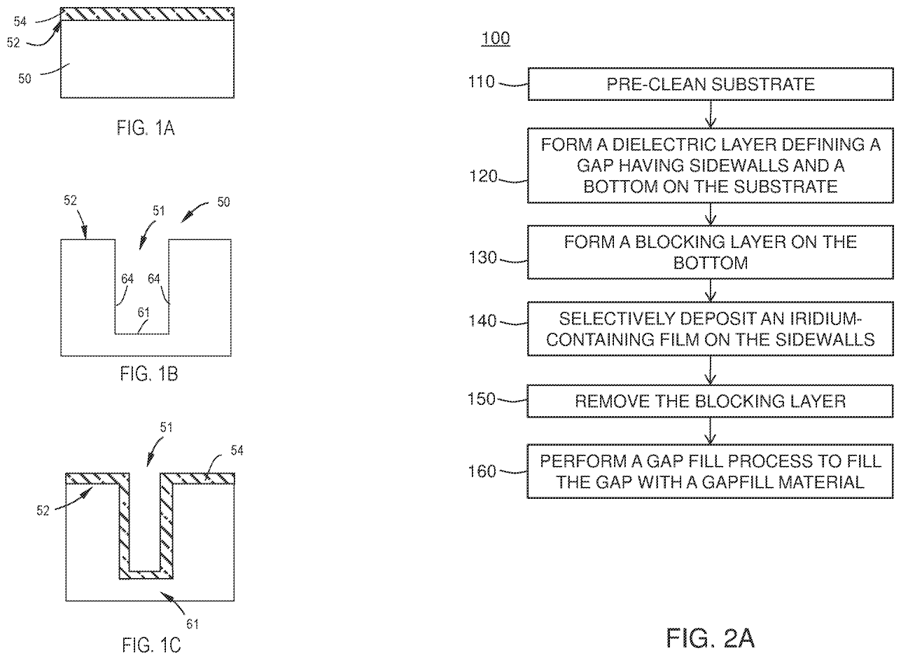

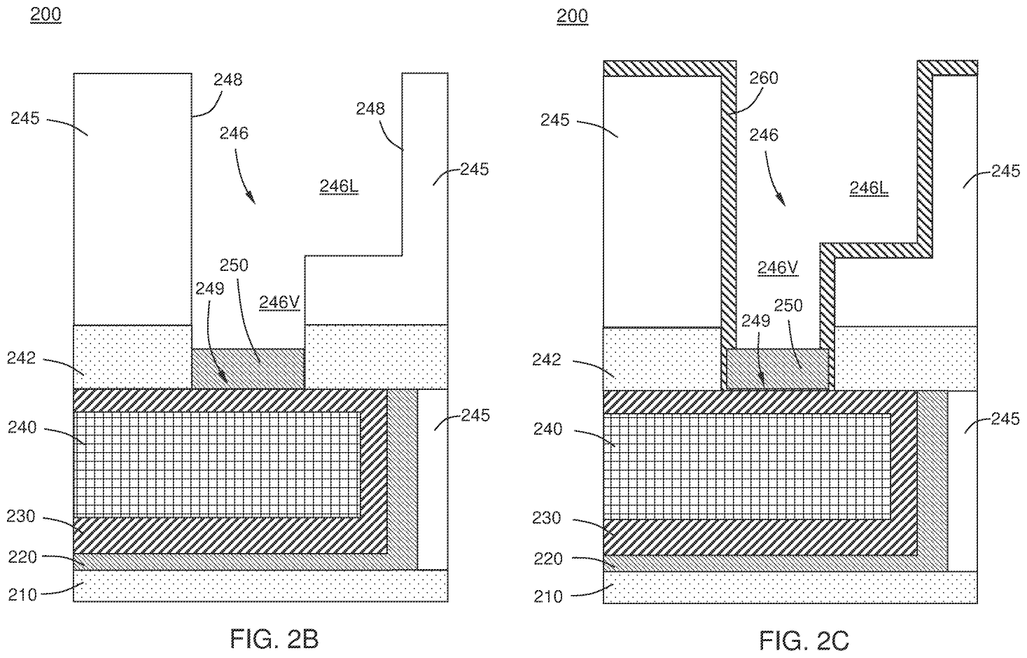

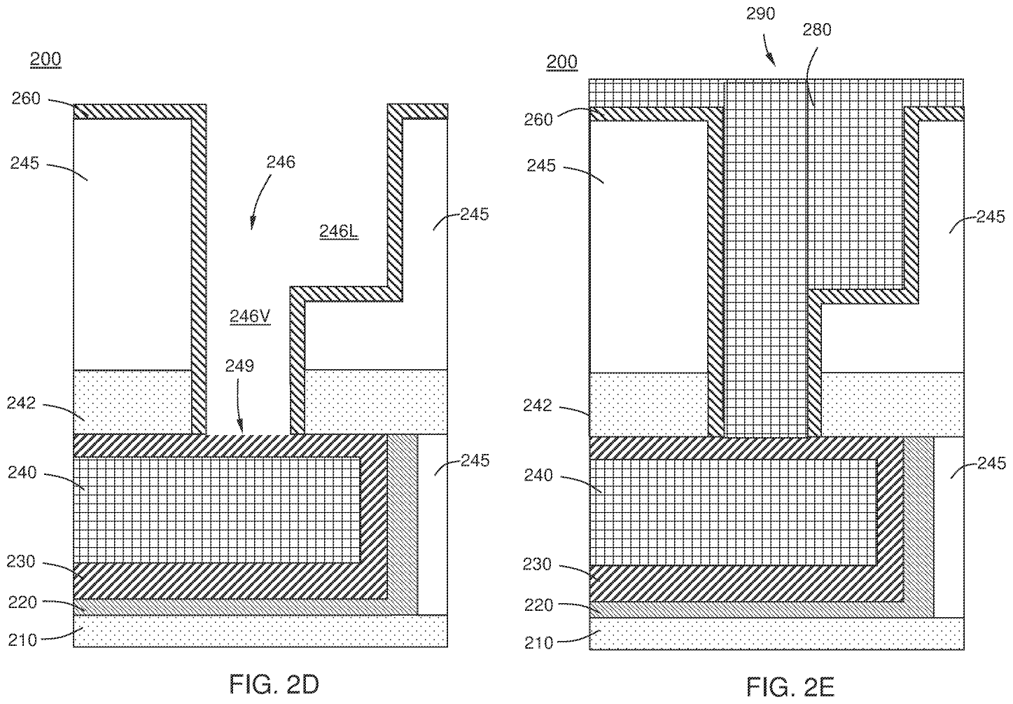

Methods of depositing iridium-containing films are described with reference to FIGS. 1A-1C. FIGS. 1A-1C illustrate cross-sectional schematic views of a substrate 50. Methods of depositing iridium-containing films in a microelectronic device fabrication process are described with reference to FIGS. 2A-2E. FIG. 2A is a process flow diagram of an exemplary method 100 of manufacturing a microelectronic device 200. FIGS. 2B-2E illustrate stages of manufacture of the microelectronic device 200 during the method 100.

Embodiments of the disclosure provide methods of depositing iridium-containing films that have desired crystallinity, grain size, continuity, and electrical conductivity properties for use as a channel material, liner or barrier layer in the miniaturize and scaling of integrated circuits.

The methods described herein, e.g., method 100, generally refer to methods of manufacturing microelectronic devices and more particularly refer to methods of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the present disclosure without undue experimentation.

FIGS. 1A-1C illustrate cross-sectional schematic views of a substrate 50 during stages of a method of depositing an iridium-containing film 54. FIG. 1A illustrates a cross-sectional schematic view of depositing the iridium-containing film 54 on a top surface 52 of the substrate 50. As will be described in further detail below, the iridium-containing film 54 is formed by exposing the substrate 50 to an iridium-containing precursor and a reactant.

FIGS. 1B-1C illustrate a cross-sectional schematic view of depositing the iridium-containing film 54 on a top surface 52 of a substrate 50 comprising at least one feature 51. The at least one feature 51 defines a gap having two opposed sidewalls 64 and a bottom surface 61.

The two opposed sidewalls 64 may comprise any suitable material. In one or more embodiments, the two opposed sidewalls 64 comprise a dielectric material, e.g., a low-K dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof. The bottom surface 61 may comprise any suitable material, such as a metallic material.

FIGS. 1B-1C show the substrate 50 having a single feature 51 for illustrative purposes; however, those skilled in the art will understand that there can be more than one feature 51. The shape of the feature 51 can be any suitable shape including, but not limited to, trenches and cylindrical vias, as described herein.

In one or more embodiments, the at least one feature 51 comprises one or more of a trench or a via. In specific embodiments, the at least one feature 51 comprises a trench. In still further embodiments, the term “at least one feature 51” and “trench 51” may be used interchangeably. The trench 51 has a depth to the bottom surface 61 and a width between the two opposed sidewalls 64. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In one or more embodiments, the aspect ratio of the trench 51 described herein is greater than or equal to about 1:1, 2:1, 5:1, 10:1, 15:1, 20:1, 25:1, 30:1, 35:1, or 40:1.

It will be appreciated by the skilled artisan that the method that is part of a gap fill process can include one or more subsequent operations after forming the iridium-containing film 54, such as, for example, filling the gap with a conductive material, and that the one or more subsequent operations can be performed without undue experimentation.

FIGS. 2B-2E illustrate stages of manufacture of the microelectronic device 200 during the method 100, and more particularly refer to methods of manufacturing interconnect structures as part of a microelectronic device fabrication process.

Referring to FIG. 2A, the method 100 comprises, at operation 110, pre-cleaning a substrate 210. In one or more embodiments, keeping the pre-cleaning process under vacuum ensures that no oxide is introduced/formed on the substrate 210 during the method 100. At operation 110, pre-cleaning the substrate 210 removes native oxides from the surface of the substrate 210.

The pre-cleaning process of operation 110 can be any suitable process. In some embodiments, the pre-cleaning process of operation 110 removes polymeric residues and copper oxide from the interconnect and maintains the integrity of the dielectric surface. As used herein, the term “substrate 210” can be used to refer to a substrate and/or a pre-cleaned substrate, unless the context clearly indicates otherwise.

At operation 120, the method 100 comprises forming a dielectric layer 245 on the substrate 210, e.g., the pre-cleaned substrate. The dielectric layer 245 comprises at least one feature defining a gap 246 having sidewalls 248 and a bottom 249. At operation 130, the method 100 comprises forming a blocking layer 250 on the bottom 249 by exposing the substrate 210 to a blocking compound. At operation 140, the method 100 comprises selectively depositing an iridium-containing film 260 on the sidewalls 248. At operation 150, the method 100 comprises removing the blocking layer 250. At operation 160, the method 100 comprises performing a gap fill process to fill the gap 246 with a gapfill material 280.

In one or more embodiments, the method 100 comprises operation 110, operation 120, operation 130, operation 140, operation 150, and operation 160. In one or more embodiments, the method 100 consists essentially of operation 110, operation 120, operation 130, operation 140, operation 150, and operation 160. In one or more embodiments, the method 100 consists of operation 110, operation 120, operation 130, operation 140, operation 150, and operation 160. In one or more embodiments, the method 100 consists of operation 130 (where the dielectric layer 245 on the substrate 210, e.g., a pre-cleaned substrate, is provided), operation 140, operation 150, and operation 160.

Referring to FIGS. 2B-2E, a portion of the microelectronic device 200 is shown during stages of manufacture. In FIG. 2B, the microelectronic device 200 comprises the substrate 210, a barrier layer 220 on the substrate 210, a metal layer 230 on the barrier layer 220, a conductive filled gap 240, an etch stop layer 242, and the dielectric layer 245 on the etch stop layer 242. The dielectric layer 245 comprises at least one feature defining the gap 246 having sidewalls 248 and the bottom 249. According to one or more embodiments, a blocking layer 250 is formed on the bottom 249 of the gap 246. It will be appreciated that in one or more embodiments, the conductive filled gap 240 forms a metal line that transfers current within the same device layer.

In one or more embodiments, the substrate 210 is a wafer, for example, a semiconductor substrate. In one or more embodiments, the substrate 210 is an etch stop layer on a wafer. In one or more embodiments, the substrate 210 is an aluminum oxide etch stop layer on a wafer.

In one or more embodiments, the barrier layer 220 comprises tantalum nitride (TaN). In one or more embodiments, the barrier layer 220 comprises tantalum nitride (TaN) formed by ALD.

In one or more embodiments, the metal layer 230 comprises one or more of ruthenium (Ru), copper (Cu), cobalt (cobalt), molybdenum (Mo), tantalum (Ta), or tungsten (W). In one or more embodiments, the metal layer 230 comprises one or more of copper (Cu), cobalt (cobalt), molybdenum (Mo), or tungsten (W). In one or more embodiments, a portion of the metal layer 230 is etched. In one or more embodiments, the blocking layer 250 is deposited on the portion of the metal layer 230 that is etched. In one or more embodiments, the conductive filled gap 240 comprises one or more of copper (Cu) or cobalt (Co). In one or more embodiments, the etch stop layer 242 comprises one or more of aluminum oxide, silicon nitride, or aluminum nitride.

In one or more embodiments, the dielectric layer 245 comprises a low-K dielectric material. In one or more embodiments, the dielectric layer 245 comprises silicon oxide (SiOₓ). In one or more embodiments, the dielectric layer 245 comprises SiOₓH_{y} (CH_{z}). Further embodiments provide that the dielectric layer 245 comprises porous or carbon-doped SiOₓ. In some embodiments, the dielectric layer 245 is a porous or carbon-doped SiOₓ layer with a K value less than about 5. In other embodiments, the dielectric layer 245 is a multilayer structure. For example, in one or more embodiments, the dielectric layer 245 comprises a multilayer structure having one or more of a dielectric layer, an etch stop layer, and a hard mask layer.

In one or more illustrated embodiments, the dielectric layer 245 comprises at least one feature defining the gap 246 having sidewalls 248 and the bottom 249. FIGS. 2A-2E illustrate substrate 210 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 1:1, 2:1, 5:1, 10:1, 15:1, 20:1, 25:1, 30:1, 35:1 or 40:1.

In some embodiments, the at least one feature defines a cylindrical via that, when filled with metal, transfers current between layers, and lines that transfer current within the same device layer. In some embodiments, the at least one feature defines the gap 246 in the dielectric layer 245. In some embodiments, the gap 246 defines a via portion 246V and a line portion 246L.

The bottom 249 of the gap 246 is defined by the metal layer 230. In one or more embodiments, the bottom 249 of the gap 246 and the metal layer 230 comprise the same material. In one or more embodiments, the bottom 249 of the gap 246 comprises one or more of ruthenium (Ru), copper (Cu), cobalt (cobalt), molybdenum (Mo), tantalum (Ta), or tungsten (W). In one or more embodiments, the bottom 249 of the gap 246 comprises one or more of copper (Cu), cobalt (cobalt), molybdenum (Mo), or tungsten (W).

In one or more embodiments, the blocking layer 250 is formed on the bottom 249 of the gap 246 in accordance with operation 130 of the method 100 (FIGS. 2A and 2B). Stated differently, in one or more embodiments, the blocking layer 250 is formed on the metal layer 230, which defines the bottom 249 of the gap 246. In one or more embodiments, the portion of the metal layer 230 on which the blocking layer 250 is formed defines the bottom 249 of the gap 246. In one or more embodiments, the blocking layer 250 is formed selectively on the bottom 249 of the gap 246 by exposing the substrate 210 to a blocking compound.

Embodiments of the present disclosure employ blocking compounds that can be used to form a blocking layer on a surface to suppress or prevent subsequent deposition on that surface. Any blocking compound that suppresses or prevents subsequent deposition on a metallic surface, e.g., the metal layer 230, which defines the bottom 249 of the gap 246 may be used.

In some embodiments, the blocking compound comprises one or more of organic ligands or inorganic ligands. In some embodiments, the blocking compound comprises organic ligands. In some embodiments, the blocking compound comprises at least one ketone group. In some embodiments, the blocking compound comprises at least one alkoxy group. In some embodiments, the blocking compound comprises at least one heterocyclic carbene group. In some embodiments, the blocking compound comprises inorganic ligands. In some embodiments, the blocking compound comprises a silicon-containing compound. In some embodiments, the blocking compound comprises at least one silane group. In some embodiments, the blocking compound comprises at least one thiol group. In some embodiments, the blocking compound comprises a phosphonate-containing compound.

In one or more embodiments, the blocking compound comprises a formula R₁—C≡C—R₂, wherein R₁ and R₂ are linear alkyl chains comprising from 5 to 15 carbon atoms. In one or more embodiments, the blocking compound comprises a formula H—C≡C—R₃, wherein R₃ is a linear alkyl chain comprising from 1 to 20 carbon atoms. In one or more embodiments, the blocking compound has a formula of R—SiH₃, wherein R is selected from a linear alkyl chain and a branched alkyl chain comprising from 2 to 20 carbon atoms.

In some embodiments, the processing conditions for exposing the substrate 210 to the blocking compound to form the blocking layer 250 may be controlled and may be varied depending on the composition of the blocking compound.

The substrate 210 may be exposed to the blocking compound at any suitable pressure for forming the blocking layer 250. In some embodiments, the substrate 210 is exposed to the blocking compound at a pressure of less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr.

The substrate 210 may be exposed to the blocking compound for any suitable time period to form the blocking layer 250 to a predetermined thickness. In some embodiments, the substrate 210 is exposed to the blocking compound for a time period in a range of from 1 second to 600 seconds.

The substrate 210 may be exposed to the blocking compound at any suitable temperature to form the blocking layer 250. In some embodiments, the substrate 210 is exposed to the blocking compound at a temperature in a range of 150° C. to 400° C., such as, for example, in a range of from 200° C. to 300° C.

The blocking layer 250 may be formed using any suitable deposition technique. In one or more embodiments, the blocking layer 250 is formed in an atomic layer deposition (ALD) chamber. In one or more embodiments, the blocking layer 250 is formed in an ex situ solution processing chamber.

Referring to FIGS. 2A and 2C, at operation 140 of the method 100, the iridium-containing film 260 is selectively deposited on the sidewalls 248 of the gap 246. In one or more embodiments, the iridium-containing film 260 covers the entirety of the sidewalls 248. In one or more embodiments, the iridium-containing film 260 does not form on the bottom 249 of the gap 246 due to the presence of the blocking layer 250 on the metal layer 230, which defines the bottom 249 of the gap 246.

The iridium-containing film 260 may be selectively deposited using any suitable deposition technique. In one or more embodiments, the iridium-containing film 260 is formed by exposing the substrate 210 to an iridium-containing precursor and a reactant.

The iridium-containing precursor comprises one or more of

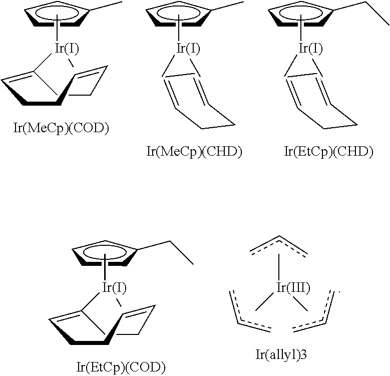

In one or more embodiments, the substrate 210 is exposed to the iridium-containing precursor and the reactant simultaneously. In one or more embodiments, the substrate 210 is exposed to the iridium-containing precursor and the reactant sequentially.

The reactant according to one or more embodiments is a thermal reactant (e.g., without the use of plasma) or a plasma composed of the reactant. In embodiments where the reactant comprises a plasma composed of the reactant, the plasma may be generated by any suitable plasma source. The plasma may include, but is not limited to, one or more of an inductively coupled plasma (ICP) source, a capacitively coupled plasma (CCP) source, a microwave source, or a remote plasma source.

In one or more embodiments, the reactant comprises one or more of hydrogen (H₂), ammonia (NH₃), an amine having a formula of R—NH₂, where R is an alkyl group or an aryl group, an amino borane having a formula of R₃N—BH₃, where each R is independently an alkyl group or an aryl group, a phosphino borane having a formula of R₃P—BH₃, where each R is independently an alkyl group or an aryl group, an alcohol having a formula of R—OH, where R is an alkyl group or an aryl group, or the following compounds

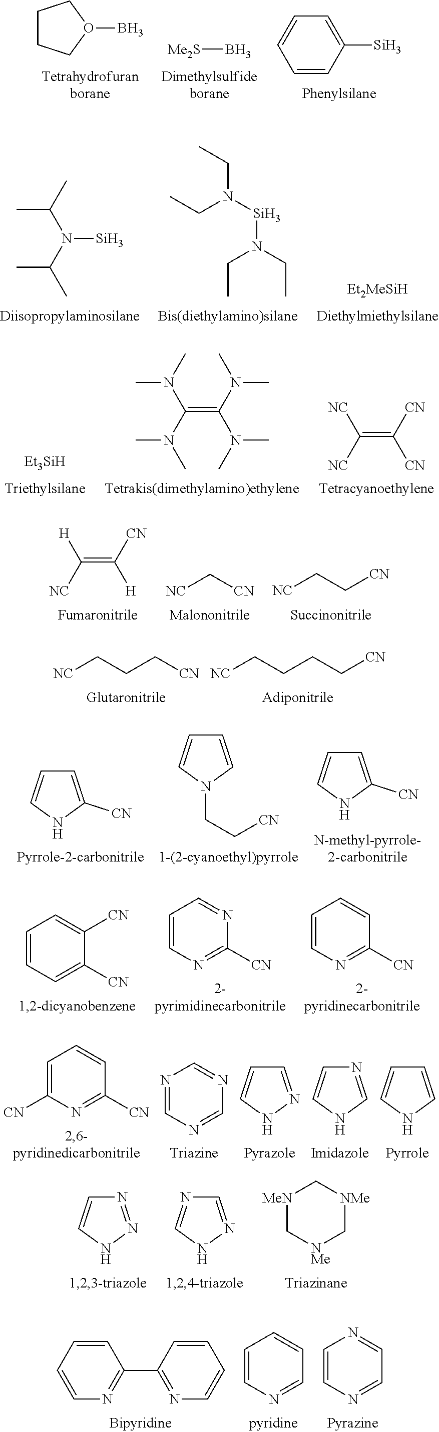

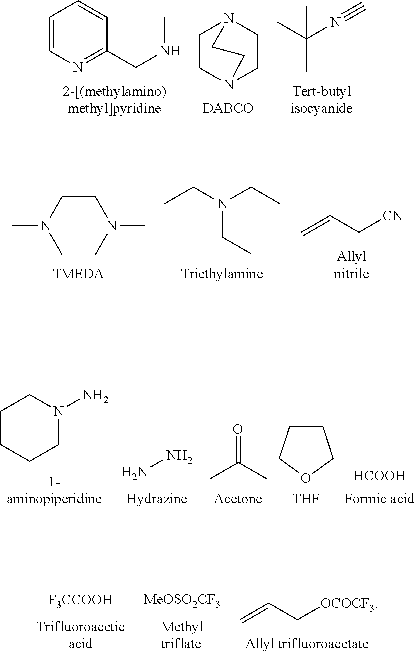

Advantageously, the iridium-containing film 260 acts as a barrier layer and/or metal liner and prevents conductive metal, such as, for example, one or more of copper (Cu), cobalt (Co), ruthenium (Ru), tungsten (W), or molybdenum (Mo), from diffusing into the dielectric layer 245.

The iridium-containing film 260 described herein can extend the metal fill and capping applications to advanced nodes, such as enabling conductive metal reflow, e.g., one or more of copper (Cu), cobalt (Co), tungsten (W), ruthenium (Ru), and/or molybdenum (Mo) reflow, in 3 nm node, 2 nm node, 1.4 nm node, and beyond, low resistivity in the middle-of-line (MOL) and back-end of line (BEOL), and memory applications.

The iridium-containing film 260 may be formed at any suitable processing conditions, and the processing conditions may vary depending upon the application in which the iridium-containing film 260 is used. The processing conditions may also vary depending on the composition of the iridium-containing precursor and the reactant.

The substrate 210 may be exposed to the iridium-containing precursor and the reactant at any suitable temperature for forming the iridium-containing film 260. In one or more, the substrate 210 is exposed to the iridium-containing precursor and the reactant at a temperature in a range of from 100° C. to 500° C.

The substrate 210 may be exposed to the iridium-containing precursor and the reactant at any suitable pressure for forming the iridium-containing film 260. In one or more, the substrate 210 is exposed to the iridium-containing precursor and the reactant at a pressure in a range of from 0.1 Torr to 760 Torr.

In some embodiments, the iridium-containing film 260 comprises greater than or equal to about 95 atomic percent iridium, or greater than or equal to about 97 atomic percent iridium, or greater than or equal to about 98 atomic percent iridium, or greater than or equal to about 99 atomic percent iridium, or greater than or equal to about 99.5 atomic percent iridium, or greater than or equal to about 99.8 atomic percent iridium.

In some embodiments, the iridium-containing film 260 contains essentially no halogen atoms. As used in this manner, the term “contains essentially no halogen atoms” means the iridium-containing film 260 comprises less than or equal to about 2%, 1% or 0.5% of halogen atoms on an atomic basis. In some embodiments, the iridium-containing film 260 is free of halogen atoms.

The iridium-containing film 260 may have any suitable thickness. In one or more embodiments, the iridium-containing film 260 has a thickness in a range of from about 2 Å to about 50 Å. In some embodiments, the iridium-containing film 260 is deposited in a single ALD cycle. In other embodiments, the iridium-containing film 260 is deposited in from 1 to 200 ALD cycles. In one or more embodiments, each cycle of the 1 to 200 ALD cycles is configured to deposit a thickness of about 0.2 Å of the iridium-containing film 260.

In one or more embodiments, when the blocking layer 250 is not present, the deposition of the iridium-containing film 260 is substantially conformal, such that the iridium-containing film 260 forms on the sidewalls 248 and on the bottom 249 of the gap 246. As used herein, a layer which is “substantially conformal” refers to a layer where the thickness is about the same throughout (e.g., on the top, middle and bottom of sidewalls 248 and on the bottom 249 of the gap 246). A layer which is substantially conformal varies in thickness by less than or equal to about 5%, 2%, 1% or 0.5%.

As described herein, in one or more embodiments, the iridium-containing film 260 does not form on the bottom 249 of the gap 246 due to the presence of the blocking layer 250. The iridium-containing film 260 selectively forms on the sidewalls 248 and extends towards the bottom 249 of the gap 246.

Referring to FIGS. 2A and 2D, at operation 160 of the method 100, the blocking layer 250 is removed. In one or more embodiments, removing the blocking layer 250 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the iridium-containing film 260.

Referring to FIGS. 2A and 2E, the method 100 includes performing a gap fill process to fill the gap 246 with a gapfill material 280 (operation 160). The gap fill process can include any suitable deposition technique. In one or more embodiments, the gap fill process comprises a physical vapor deposition (PVD) process.

The gapfill material 280 may include any suitable material, such as a conductive material. In one or more embodiments, the gapfill material 280 comprises one or more of copper (Cu), cobalt (Co), ruthenium (Ru), tungsten (W), or molybdenum (Mo). In one or more embodiments, the gap fill process comprises filling the gap 246 with one or more of copper (Cu), cobalt (Co), ruthenium (Ru), tungsten (W), or molybdenum (Mo) by physical vapor deposition (PVD). In one or more embodiments, the gap fill process comprises filling the gap 246 with one or more of copper (Cu), cobalt (Co), tungsten (W), or molybdenum (Mo) by physical vapor deposition (PVD).

The gapfill material 280 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gapfill material 280 an atomic basis, comprises seams and/or voids. Advantageously, in one or more embodiments, the gapfill material 280 is free of seams and/or voids.

In one or more embodiments, after filling the gap 246 with the gapfill material 280, a completed interconnect structure, e.g., interconnect structure 290 is formed, such that additional interconnect structures may be formed on top of or below the interconnect structure 290.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer. In some embodiments, the optional post-processing operation comprises annealing the substrate. In some embodiments, the annealing process is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate is annealed for a predetermined time in the range of about 15 seconds to about 90 minutes, or in the range of about 1 minute to about 60 minutes. In some embodiments, annealing the substrate increases the density, decreases the resistivity and/or increases the purity of the layers, such as iridium-containing film 260.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein.

Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc., processes throughout the carousel path.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Additional embodiments are directed to a cluster tool used to manufacture the microelectronic devices described herein, e.g., microelectronic device 200, and perform the methods described herein, e.g., method 100. In one or more embodiments, the cluster tool comprises a pre-cleaning chamber to pre-clean the substrate and a deposition chamber for forming a dielectric layer including at least one feature defining a gap having sidewalls and a bottom. In one or more embodiments, a pre-cleaned substrate comprising a dielectric layer including at least one feature defining a gap having sidewalls and a bottom is provided.

In one or more embodiments, the cluster tool comprises a deposition chamber for forming a blocking layer 250. In one or more embodiments, the cluster tool comprises an atomic layer deposition (ALD) chamber for forming the blocking layer 250. In one or more embodiments, the cluster tool comprises an atomic layer deposition (ALD) chamber for selectively depositing the iridium-containing film 260. In one or more embodiments, the cluster tool comprises a chamber for removing the blocking layer. Advantageously, in one or more embodiments, the same processing chamber may be used to selectively deposit the iridium-containing film 260 and to remove the blocking layer. In one or more embodiments, the cluster tool comprises a deposition chamber for performing the gap fill process to fill the gap with a gapfill material. In one or more embodiments, the cluster tool comprises a physical vapor deposition (PVD) chamber for performing the gap fill process to fill the gap with a gapfill material.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIGS. 1A-1C and 2A-2E.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing an iridium-containing film, the method comprising:
exposing a semiconductor substrate to an iridium-containing precursor and a reactant to form the iridium-containing film, the iridium-containing precursor comprising one or more of

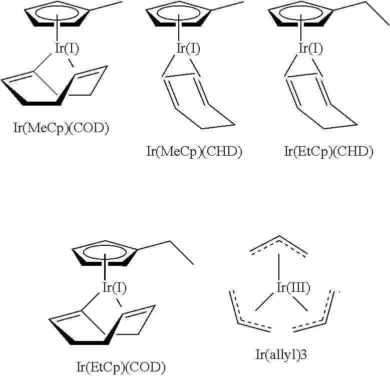

2. The method of claim 1, wherein the semiconductor substrate comprises at least one feature, the at least one feature defining a gap having sidewalls and a bottom.

3. The method of claim 2, wherein the sidewalls comprise a dielectric material and the bottom comprises a metallic material.

4. The method of claim 1, wherein the semiconductor substrate is exposed to the iridium-containing precursor and the reactant simultaneously.

5. The method of claim 1, wherein the semiconductor substrate is exposed to the iridium-containing precursor and the reactant sequentially.

6. The method of claim 2, wherein the iridium-containing film forms conformally along the sidewalls and the bottom of the gap.

7. The method of claim 1, wherein the reactant is a thermal reactant or a plasma composed of the reactant.

8. The method of claim 1, wherein the reactant comprises one or more of hydrogen (H₂), ammonia (NH₃), an amine having a formula of R—NH₂, where R is an alkyl group or an aryl group, an amino borane having a formula of R₃N—BH₃, where each R is independently an alkyl group or an aryl group, a phosphino borane having a formula of R₃P—BH₃, where each R is independently an alkyl group or an aryl group, an alcohol having a formula of R—OH, where R is an alkyl group or an aryl group, or the following compounds

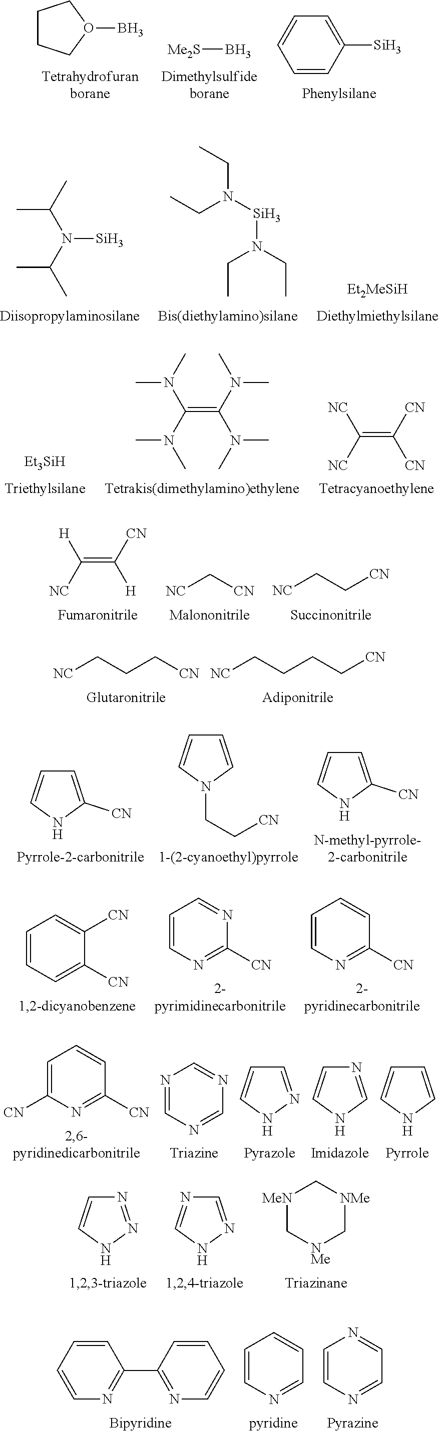

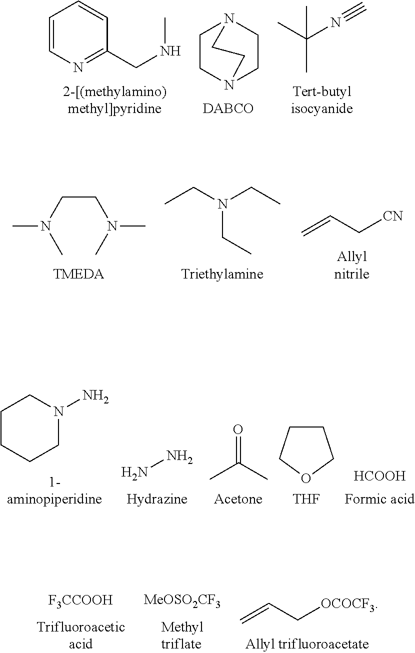

9. The method of claim 1, performed at a temperature in a range of from 100° C. to 500° C.

10. The method of claim 1, performed at a pressure in a range of from 0.1 Torr to 760 Torr.

11. The method of claim 1, wherein the iridium-containing film comprises greater than or equal to about 99% iridium atoms.

12. The method of claim 1, wherein the iridium-containing film contains essentially no halogen atoms.

13. A method of manufacturing a semiconductor device, the method comprising:
exposing a semiconductor substrate to an iridium-containing precursor and a reactant to form an iridium-containing film, the semiconductor substrate comprising at least one feature, the at least one feature defining a gap having sidewalls comprised of a dielectric material and a bottom comprised of a metallic material, the iridium-containing precursor comprising one or more of 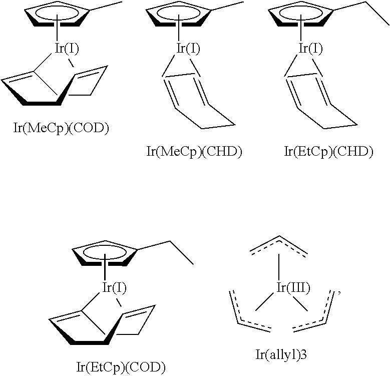
wherein the method is performed at a temperature in a range of from 100° C. to 500° C. and a pressure in a range of from 0.1 Torr to 760 Torr, the iridium-containing film comprises greater than or equal to about 99% iridium atoms, and the iridium-containing film contains essentially no halogen atoms.

14. The method of claim 13, wherein the semiconductor substrate is exposed to the iridium-containing precursor and the reactant simultaneously.

15. The method of claim 13, wherein the semiconductor substrate is exposed to the iridium-containing precursor and the reactant sequentially.

16. The method of claim 13, wherein the reactant is a thermal reactant or a plasma composed of the reactant.

17. The method of claim 13, wherein the reactant comprises one or more of hydrogen (H₂), ammonia (NH₃), an amine having a formula of R—NH₂, where R is an alkyl group or an aryl group, an amino borane having a formula of R₃N—BH₃, where each R is independently an alkyl group or an aryl group, a phosphino borane having a formula of R₃P—BH₃, where each R is independently an alkyl group or an aryl group, an alcohol having a formula of R—OH, where R is an alkyl group or an aryl group, or the following compounds

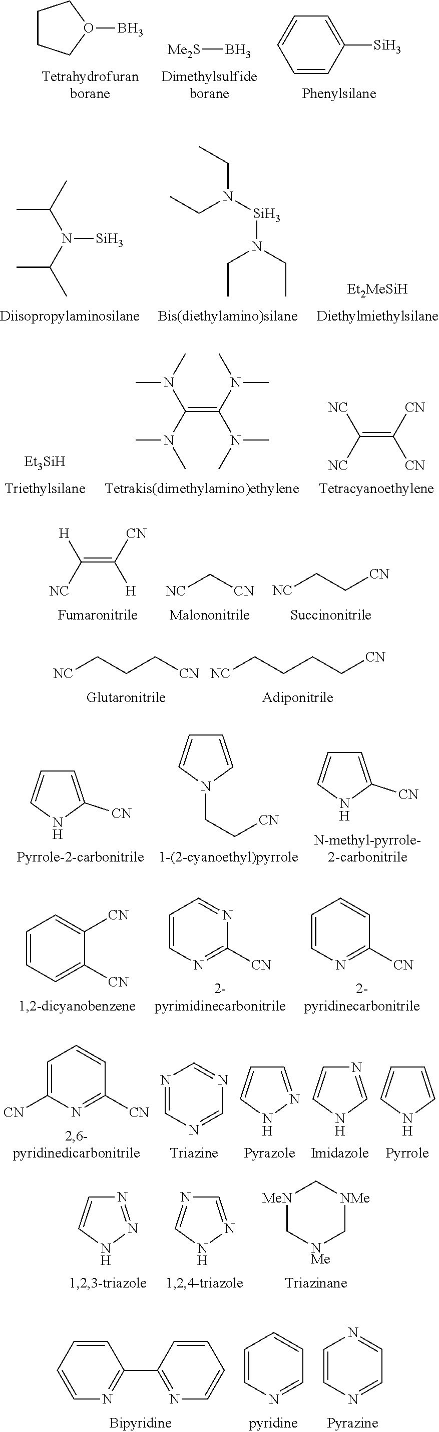

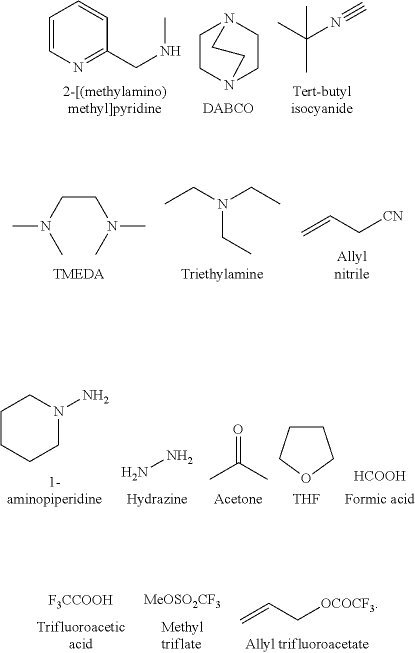

18. A method of manufacturing a microelectronic device, the method comprising:
forming a dielectric layer on a substrate, the dielectric layer including at least one feature defining a gap having sidewalls and a bottom;
forming a blocking layer on the bottom;
selectively depositing an iridium-containing film on the sidewalls;
removing the blocking layer; and
performing a gap fill process to fill the gap with a gapfill material comprising one or more of copper (Cu), cobalt (Co), ruthenium (Ru), tungsten (W), or molybdenum (Mo).

19. The method of claim 18, wherein the iridium-containing film is selectively deposited by exposing the substrate to an iridium-containing precursor and a reactant, the iridium-containing precursor comprising one or more of

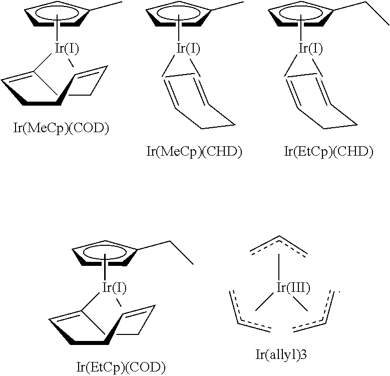

20. The method of claim 19, wherein the reactant comprises one or more of hydrogen (H₂), ammonia (NH₃), an amine having a formula of R—NH₂, where R is an alkyl group or an aryl group, an amino borane having a formula of R₃N—BH₃, where each R is independently an alkyl group or an aryl group, a phosphino borane having a formula of R₃P—BH₃, where each R is independently an alkyl group or an aryl group, an alcohol having a formula of R—OH, where R is an alkyl group or an aryl group, or the following compounds 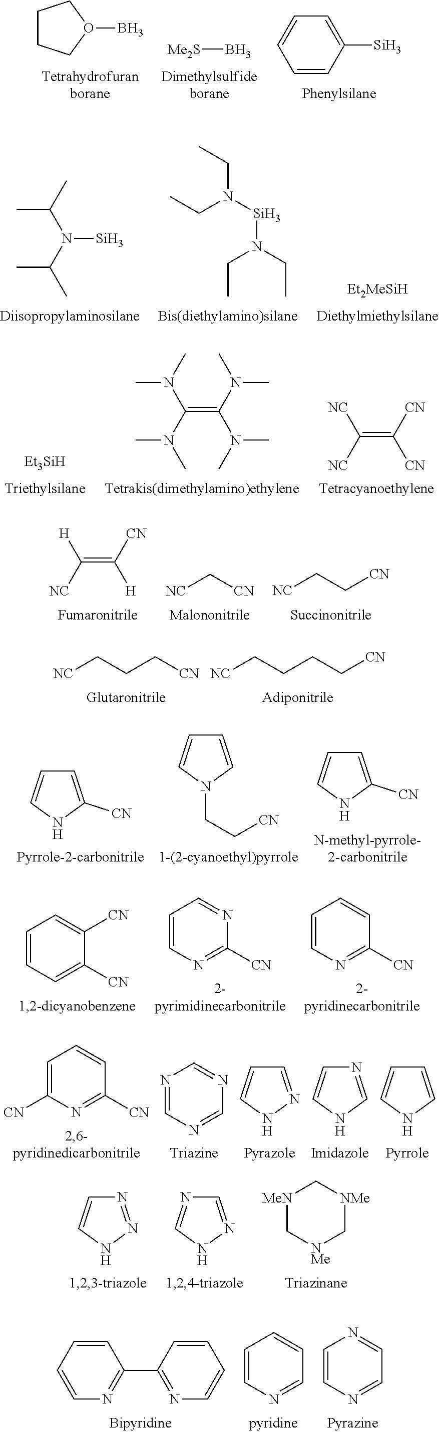 [chemical structure]
